(19) United States
(12) Patent Application Publication
(10) Pub. No.: US 2021/0348037 A1
(43) Pub. Date: Nov. 11, 2021

(54) CONDUCTIVE ADHESIVE AND A BONDING METHOD OF CIRCUIT BOARD

(71) Applicant: WUHAN CHINA STAR OPTOELECTRONICS SEMICONDUCTOR DISPLAY TECHNOLOGY CO., LTD., Wuhan (CN)

(72) Inventors: Siheng GAO, Wuhan (CN); Jinlong TAN, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/334,362

(22) PCT Filed: Sep. 25, 2018
(86) PCT No.: PCT/CN2018/107399

§ 371 Date: Mar. 19, 2019

(30) Foreign Application Priority Data
Aug. 10, 2018 (CN) 201810910055.4

(51) Int. Cl. C09J 9/02; H05K 3/32; H05K 3/00

(52) U.S. Cl. CPC C09J 9/02; H05K 3/323; H05K 3/0023; H05K 2201/10136; C09J 2465/00; C09J 2467/00; C09J 2463/00

(57) ABSTRACT

A conductive adhesive and a bonding method of circuit board are provided. The conductive adhesive includes a substrate and an insulating region formed on a surface of the substrate and a conductive region. The insulating region includes a plurality of insulating retaining walls arranged along a same direction and in intervals. The conductive region includes a plurality of conductive adhesive bodies and the conductive adhesive bodies are filled in gaps between the adjacent insulating retaining walls.

### FIELD OF INVENTION

The present invention relates a display technology, and more specifically, to a conductive adhesive and a bonding method of the circuit board.

### BACKGROUND

With development of society, liquid crystal displays (LCD) products are gradually unable to satisfy customer needs for portable display panels. Instead, organic light-emitting diode (OLED) products have become one of great potential markets in the coming display industry and can satisfy high demands the mobile portable market.

In the OLED technologies, bonding process plays an important role in the module processes. The bonding process directly influences display effect of the display screen. Poor bonding processes may result in short circuit of the display panel, display displacement and falling of parts and further may result in bright points, dark points, bright lines, dark lines, uneven display, and blank screen.

Additionally, attachment of anisotropic conductive film (ACF) is also important. ACF is a conductive adhesive which is conductive in the vertical direction but insulated in the horizontal direction. ACF includes conductive adhesive and conductive particles. Conductive adhesive is an insulated resin such as allyl monomer initiator, epoxy monomer initiator, thermoplastic material, or thermosetting material.

FIG. 1 shows a conventional ACF structure. In conventional ACF, conductive particles 11 are distributed evenly in the adhesive material 12. Conductive particles 11 are freely distributed and there are certain gaps between the conductive particles 11. By controlling the gaps of the conductive particles is able to insulate the conductive particles 11 from one another in a horizontal direction. However, such solution has several defects. First, by controlling the gaps of the conductive particles may result in short circuiting because the gaps are too narrow and conductive particles 11 are unevenly distributed. Second, due to the unevenly distributed conductive particles 11, the effective conductive particles on the substrate are cannot be precisely controlled. FIG. 2 shows a flawed displaying resulted from ACF. Referring to FIG. 2, since the distribution of the conductive particles cannot be controllable, it may result in the short circuit. Therefore, a solution for providing a conductive adhesive and a bonding method of circuit board to solve several aforementioned issues is needed.

### SUMMARY OF INVENTION

The present invention provides a conductive adhesive and a bonding method of circuit board to solve several issues resulted from current anisotropic conductive adhesives. For examples, conductive particles of certain portion are not evenly distributed and the intervals of the conductive particles along a horizontal direction are too narrow to result in a short circuit and to higher cost of the conductive adhesive.

In order to realize aforementioned purpose, the present invention provides an embodiment described as below.

In one aspect of the present invention, the present invention provides a conductive adhesive includes a substrate, an insulating region formed on a surface of the substrate and a conductive region. The insulating region includes a plurality of insulating retaining walls arranged along a same direction and in intervals, the conductive region comprises a plurality of conductive adhesive bodies, the conductive adhesive bodies fill in gaps between the adjacent insulating retaining walls, and the insulating retaining walls are made of insulating resin.

In one embodiment of the present invention, the conductive adhesive bodies comprise thermosetting resin and conductive particles disposed in the thermosetting resin.

In one embodiment of the present invention, the conductive particles are uniformly distributed in the thermosetting resin.

In one embodiment of the present invention, the thermosetting resin is at least one selected from a group consisting of modified phenolic resin, epoxy resin and unsaturated polyester resin.

According to another aspect of the present invention, the present invention provides a bonding method of circuit board, comprising:
step s10: providing a substrate, the substrate comprising a bonding area and a plurality of first terminals distributed with intervals on a surface of the bonding area;
step s20: coating a photoresist layer on the bonding area, the photoresist layer comprising a first photoresist and a second photoresist, and utilizing a first goal photomask to expose, etch and develop to etch off the first photoresist while the second photoresist is remained, wherein the first photoresist is coated on the first terminals and the second photoresist is coated between the first terminals;
step s30: dropping a solution containing conductive adhesive bodies to a position where the first photoresist originally exists and utilizing a heated plate to press the solution and precuring the solution to form a conductive region comprising conductive adhesive bodies distributed with intervals;
step s40: utilizing a second goal photomask to expose, etch and develop to etch off the second photoresist between the conductive adhesive bodies; and
step s50: forming a plurality of insulating retaining walls between the adjacent conductive adhesive bodies and providing a circuit board which has thereon a plurality of second terminals disposed corresponding to the first terminals, respectively, and utilizing the heated plate to press the circuit board to complete the bonding of the circuit board after the second terminals are aligned and connected with the first terminals through the conductive adhesive bodies. The insulating region comprises the insulating retaining walls, the conductive region comprises the conductive adhesive bodies and the conductive adhesive bodies are formed in the gaps between the adjacent insulating retaining walls.

In one embodiment of the present invention, the conductive adhesive body includes thermosetting resin and conductive particles disposed in the thermosetting resin.

In one embodiment of the present invention, the insulating retaining walls includes insulating resin.

In one embodiment of the present invention, the step s30 further includes doping conductive particles with a predetermined proportion in liquid-state thermosetting resin in and adding a foaming agent into the liquid-state thermosetting resin and stirring the liquid-state thermosetting resin uniformly to form the conductive adhesive body solution and procure the conductive adhesive body solution to form the conductive adhesive bodies.

In one embodiment of the present invention, the thermosetting resin is at least one selected from a group consisting of modified phenolic resin, epoxy resin and unsaturated polyester resin.

In one embodiment of the present invention, the step s50 further includes adding a foaming agent into insulating resin solution and stirring the insulating resin solution uniformly to form an insulating retaining walls solution and dropping the insulating retaining walls solution between the adjacent conductive adhesive bodies to cure insulating retaining walls solution to form the insulating retaining walls.

In one embodiment of the present invention, the step s30, the step s40 and the step s50 are operated in a vacuum environment.

In one embodiment of the present invention, the substrate utilizes the first terminals to communicate with the circuit board.

According to one aspect of the present invention, the present invention provides a conductive adhesive, including a substrate, an insulating region formed on a surface of the substrate and a conductive region. The insulating region includes a plurality of insulating retaining walls arranged along a same direction and in intervals. The conductive region includes a plurality of conductive adhesive bodies and the conductive adhesive bodies are filled in gaps between the adjacent insulating retaining walls.

In one embodiment of the present invention, the conductive adhesive bodies include thermosetting resin and conductive particles disposed in the thermosetting resin.

In one embodiment of the present invention, the thermosetting resin is at least one selected from a group consisting of modified phenolic resin, epoxy resin and unsaturated polyester resin.

In one embodiment of the present invention, the conductive particles are uniformly distributed in the thermosetting resin.

One advantage of the present invention is to provide a conductive adhesive and a bonding method of circuit board. By utilizing the conductive adhesive, the present invention prepares an insulating region and a conductive region to satisfy that the conductive adhesive is conductive along a vertical direction and is insulated along a transverse direction and to guarantee the conductive particles are uniformly distributed and to reduce the production costs of the conductive adhesive.

### BRIEF DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

FIG. 1 is a structural schematic diagram of a conventional anisotropic conductive adhesive.

FIG. 2 is a schematic diagram of a short circuit resulting from the conductive adhesives.

FIG. 3 is a structural schematic diagram of a conductive adhesive according to the present invention.

FIG. 4 is a schematic bonding method flowchart of a circuit board according to the present invention.

FIG. 5a-5e are schematic bonding method diagrams of the circuit board according to the present invention.

FIG. 6 is another schematic bonding method diagrams of the circuit board according to the present invention.

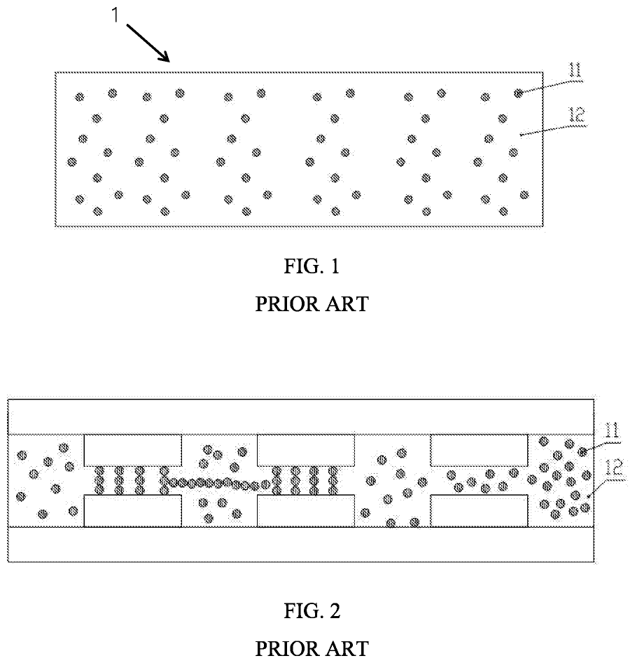

### DETAILED DESCRIPTION OF PREFERRED EMBODIMENTS

The embodiments of the present disclosure are described in detail hereinafter. Examples of the described embodiments are given in the accompanying drawings, wherein the identical or similar reference numerals constantly denote the identical or similar elements or elements having the identical or similar functions. In the description of the present disclosure, it should be understood that terms such as “upper,” “lower,” “front,” “rear,” “left,” “right,” “inside,” “outside,” “side” as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure. Similar reference numerals denote the identical structures.

The present invention provides a conductive adhesive and a bonding method of circuit board to solve several issues resulted from current anisotropic conductive adhesives. For example, conductive particles of certain portion are not evenly distributed and the intervals of the conductive particles along a horizontal direction are too narrow to result in a short circuit and to higher cost of the conductive adhesive. The present invention provides a conductive adhesive and a bonding method of circuit board. The present embodiment can solve this issue.

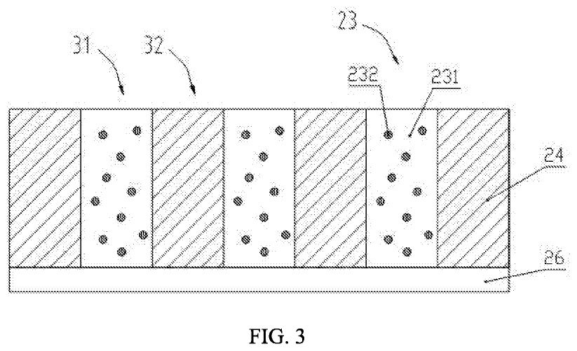

Further details are provided and explained by utilizing the figures and embodiments of the present invention. FIG. 3 is a schematic structural diagram of the conductive adhesive according to an embodiment of the present invention.

Referring to FIG. 3, FIG. 3 is a schematic structural diagram of the conductive adhesive according to an embodiment of the present invention.

The present invention provides a conductive adhesive includes a substrate 26, an insulating region 32 formed on a surface of the substrate 26 and a conductive region 31. The insulating region 32 includes a plurality of insulating retaining walls 24 arranged along a same direction and in intervals. The conductive region 31 includes a plurality of conductive adhesive bodies 23. The conductive adhesive bodies 23 are filled in gaps between the adjacent insulating retaining walls 24, and the insulating retaining walls 24 are made of insulating resin.

In one embodiment of the present invention, the conductive adhesive bodies 23 comprise thermosetting resin 231 and conductive particles 232 disposed in the thermosetting resin 231.

The thermosetting resin 231 is solidified in a high-temperature environment. Instead, in a low-temperature environment, the thermosetting resin 231 is soften and In one embodiment of the present invention, the thermosetting resin 231 is at least one selected from a group consisting of modified phenolic resin, epoxy resin and unsaturated polyester resin. Furthermore, the thermosetting resin 231 is not limited by the aforementioned examples.

In one embodiment of the present invention, the insulating retaining walls 24 are made of insulating resin. The insulating retaining walls 24 can be made of the same materials as the thermosetting resin 231 or different materials from the thermosetting resin 231. The function of the insulating retaining walls 24 is to isolate the conductive adhesive bodies 23 from each other to prevent from happening of the short circuit.

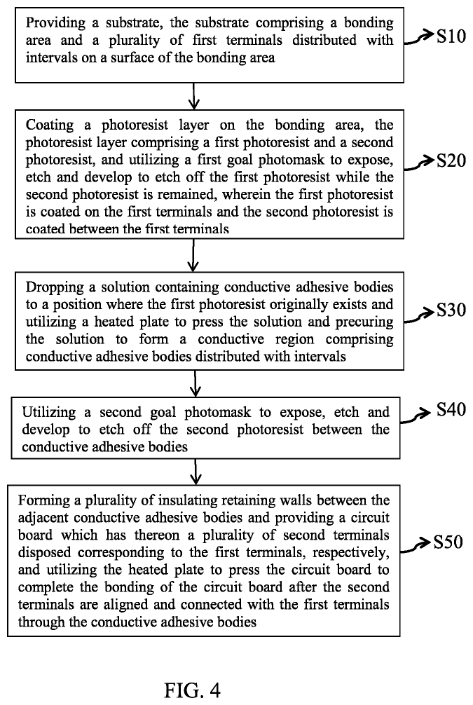

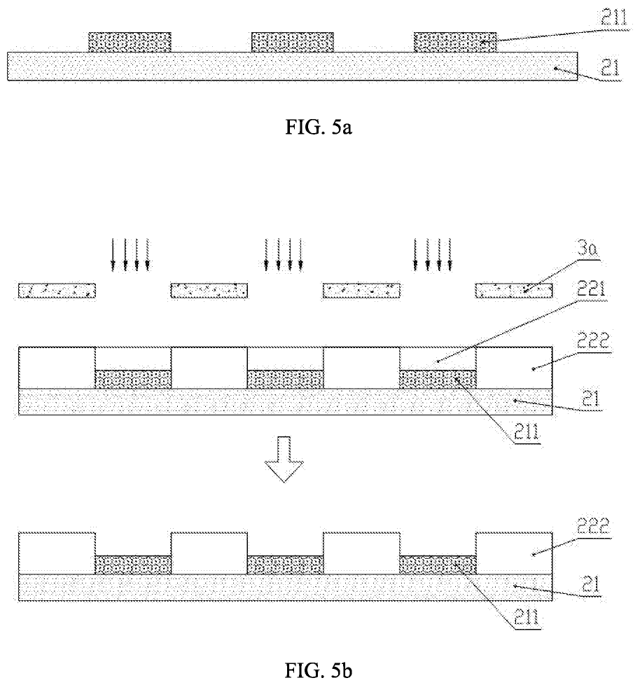

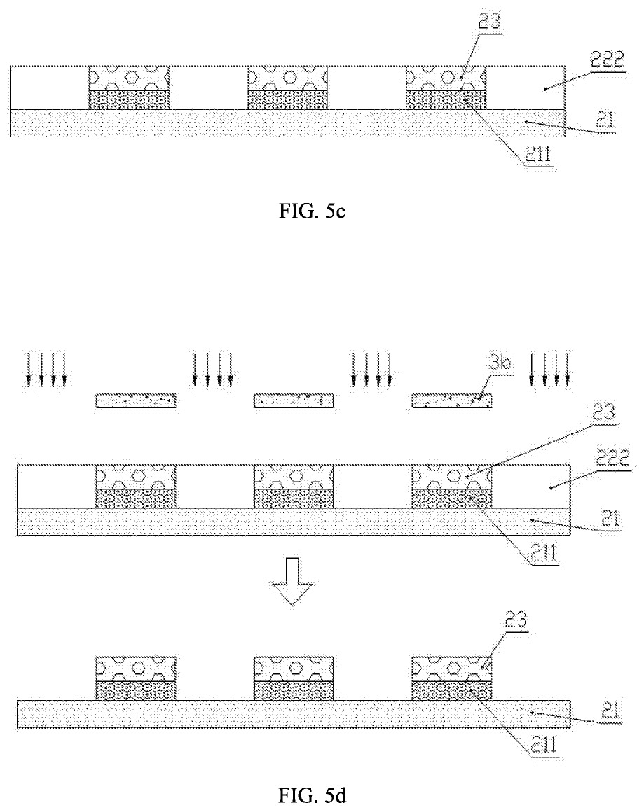

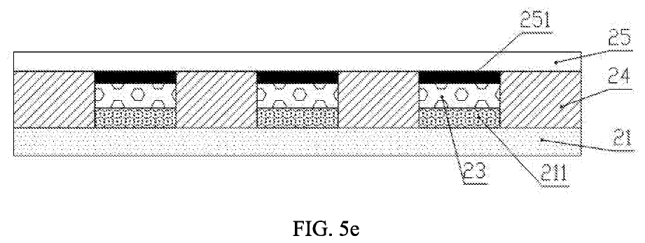

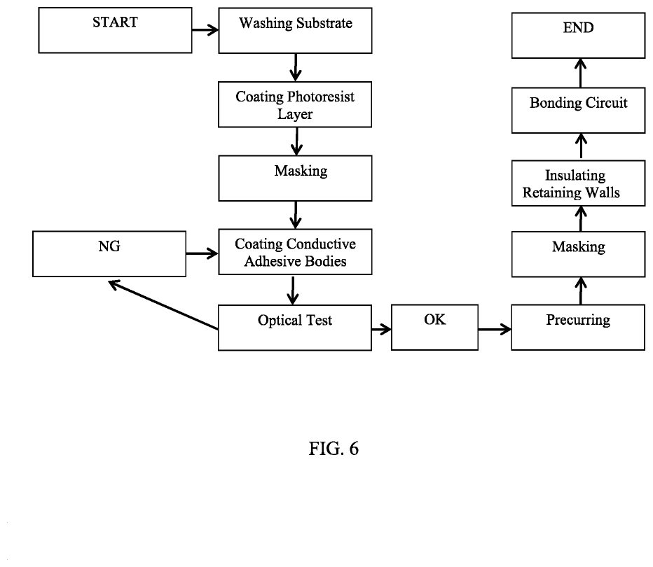

According to another aspect of the present invention, please refer to FIG. 4 and FIGS. 5a-5e. FIG. 4 is a schematic flowchart diagram of the bonding method of circuit board according to an embodiment of the present invention. FIGS. 5a-5e are schematic diagrams of the bonding method of circuit board according to an embodiment of the present invention.

The present invention provides a bonding method of circuit board, comprising:
step s10: providing a substrate, the substrate comprising a bonding area 21 and a plurality of first terminals 211 distributed with intervals on a surface of the bonding area 21. In one embodiment of the present invention, at the beginning, clean up the bonding area 21 and control the number of the particles in the bonding area 21. The first terminal 211 is used for communication between the substrate and circuit board 25. It requires utilizing the anisotropic conductive adhesive to prevent the adjacent first terminals from happening of the short circuit.

Referring to FIG. 5b, step s20: coating a photoresist layer 22 on the bonding area 21, the photoresist layer 22 comprising a first photoresist 221 and a second photoresist 222, and utilizing a first goal photomask 3a to expose, etch and develop to etch off the first photoresist 221 while the second photoresist 222 is remained, wherein the first photoresist 221 is coated on the first terminals 211 and the second photoresist 222 is coated between the first terminals 211. The main purpose of this step is utilizing the photoresist layer 22 to do the etching process. Utilize the first goal photomask 3a to etch a groove for dropping the solution of the conductive adhesive bodies 23 into it to form and secure the shape and distribution of the conductive adhesive bodies 23. In one embodiment of the present invention, the first photoresist 221 is located at the same position as the conductive adhesive bodies 23. The second photoresist 222 is located at the same position as the insulating retaining walls 24.

Referring to FIG. 5c, step s30: dropping a solution containing conductive adhesive bodies to a position where the first photoresist 211 originally exists and utilizing a heated plate to press the solution. Precure the solution to form a conductive region comprising conductive adhesive bodies 23 distributed with intervals. In one embodiment of the present invention, after finishing the dropping of the solution of the conductive adhesive bodies 23, it requires to do the optical test for the conductive adhesive bodies 23 to detect the distribution of the conductive particles 232 and small particles on the first terminal 211. If the test results satisfy the standard of the conductive adhesive, it shall precure the conductive adhesive bodies 23. If the test results do not satisfy the standard of the conductive adhesive, it requires to correct the dropping of the solution of the conductive adhesive bodies 23 and to do the optical test again until the distribution of the conductive particles 232 and small particles on the first terminal 211 satisfies the standard of the conductive adhesive.

In one embodiment of the present invention, the preparing method of the solution of the conductive adhesive bodies 23 is to dope conductive particles 232 at an effective proportion into a liquid thermosetting resin 231 and add the foam drainage agent into the liquid thermosetting resin 231. Then, stir the liquid thermosetting resin 231 to uniformly form a solution of the conductive adhesive bodies and precure the solution of the conductive adhesive bodies to form the conductive adhesive bodies 23. By stirring up the liquid thermosetting resin 231 uniformly, the present invention can prevent the conductive particles from dropping in the thermosetting resin 231 to make sure the coating process of the conductive adhesive bodies 23 to result in a uniform distribution of the conductive particles 232. Add the foam drainage agent at an effective amount into the liquid thermosetting resin 231 and stir in a vacuum environment to help exclude the bubbles out from the liquid thermosetting resin 231 and prevent the bubbles from forming inside the thermosetting resin 231. Meanwhile, in order to prevent the coating processes from forming too many bubbles, the dropping of the solution of the conductive adhesive bodies should be operated in the vacuum environment. In one embodiment of the present invention, after the dropping process of the solution of the conductive adhesive bodies, it requires to perform the precurring process. Under a certain pressure, a certain temperature (lower than the solidification temperature of the thermosetting resin) and a vacuum environment, the solution of the conductive adhesive bodies will soften at the beginning and increase the fluidity and exclude the bubbles in the solution of the conductive adhesive bodies. Further, the heating process lowers the fluidity of the solution of the conductive adhesive bodies. The solution of the conductive adhesive bodies is formed in a gel state and forms the conductive adhesive bodies 23 to be fixed on a surface of the first terminals 211.

Referring to FIG. 5d, step s40 is to utilize a second goal photomask 3b to expose, etch and develop to etch off the second photoresist 222 between the conductive adhesive bodies 23. The step s40 is a process to remove the photoresist. In one embodiment, the step s40 is to remove the second photoresist 222 between the first terminals 211 and to utilize the second mask to 3b to shield the light on the area which the conductive adhesive bodies 23 are located. The present invention utilizes the ultraviolet light to shine on the second photoresist 222 and utilize the developing solution to wash and to remove the second photoresist 222.

Referring to FIG. 5e, step s50: forming a plurality of insulating retaining walls 24 between the adjacent conductive adhesive bodies 23 and providing a circuit board 25 which has thereon a plurality of second terminals 251 disposed corresponding to the first terminals 211, respectively, and utilizing the heated plate to press the circuit board 25 to complete the bonding of the circuit board after the second terminals 251 are aligned and connected with the first terminals 211 through the conductive adhesive bodies 23. The insulating region comprises the insulating retaining walls 24, the conductive region comprises the conductive adhesive bodies 23 and the conductive adhesive bodies 23 are formed in the gaps between the adjacent insulating retaining walls 24.

In one embodiment of the present invention, the step s50 further includes: adding the foam drainage agent into a solution of insulation resin. Then, stir the solution of insulation resin to uniformly form a solution of insulating retaining walls and drop the solution of insulating retaining walls between the conductive adhesive bodies to cure the solution of insulating retaining walls and to form the insulating retaining walls 24. The forming principles of the insulating retaining walls 24 are similar to the forming principles of the conductive adhesive bodies 23. Therefore, the forming principles of the insulating retaining walls 24 can be as a reference for the forming principles of the conductive adhesive bodies 23.

In one embodiment of the present invention, the conductive adhesive body 23 includes thermosetting resin 231 and conductive particles 232 disposed in the thermosetting resin 231. The insulating retaining walls 24 are made of insulating resin.

In one embodiment of the present invention, the thermosetting resin 231 is at least one selected from a group consisting of modified phenolic resin, epoxy resin and unsaturated polyester resin.

One advantage of the present invention is to provide a conductive adhesive and a bonding method of circuit board. By utilizing the conductive adhesive, the present invention prepares an insulating region and a conductive region to satisfy that the conductive adhesive is conductive along a vertical direction and is insulated along a transverse direction and to guarantee the conductive particles are uniformly distributed and to reduce the production costs of the conductive adhesive.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

1. A conductive adhesive, comprising:
a substrate, an insulating region formed on a surface of the substrate, and a conductive region;
wherein the insulating region comprises a plurality of insulating retaining walls arranged along a same direction and in intervals, the conductive region comprises a plurality of conductive adhesive bodies, the conductive adhesive bodies fill in gaps between the adjacent insulating retaining walls, and the insulating retaining walls are made of insulating resin.

2. The conductive adhesive according to claim 1, wherein the conductive adhesive bodies comprise thermosetting resin and conductive particles disposed in the thermosetting resin.

3. The conductive adhesive according to claim 2, wherein the conductive particles are uniformly distributed in the thermosetting resin.

4. The conductive adhesive according to claim 2, wherein the thermosetting resin is at least one selected from a group consisting of modified phenolic resin, epoxy resin, and unsaturated polyester resin.

5. A bonding method of circuit board, comprising:
step s10: providing a substrate, the substrate comprising a bonding area and a plurality of first terminals distributed with intervals on a surface of the bonding area;
step s20: coating a photoresist layer on the bonding area, the photoresist layer comprising a first photoresist, and a second photoresist, and utilizing a first goal photomask to expose, etch, and develop to etch off the first photoresist while the second photoresist is remained, wherein the first photoresist is coated on the first terminals and the second photoresist is coated between the first terminals;
step s30: dropping a solution containing conductive adhesive bodies to a position where the first photoresist originally exists and utilizing a heated plate to press the solution and precuring the solution to form a conductive region comprising conductive adhesive bodies distributed with intervals;
step s40: utilizing a second goal photomask to expose, etch, and develop to etch off the second photoresist between the conductive adhesive bodies; and
step s50: forming a plurality of insulating retaining walls between the adjacent conductive adhesive bodies and providing a circuit board which has thereon a plurality of second terminals disposed corresponding to the first terminals, respectively, and utilizing the heated plate to press the circuit board to complete the bonding of the circuit board after the second terminals are aligned and connected with the first terminals through the conductive adhesive bodies;
wherein the insulating region comprises the insulating retaining walls, the conductive region comprises the conductive adhesive bodies and the conductive adhesive bodies are formed in the gaps between the adjacent insulating retaining walls.

6. The bonding method of circuit board according to claim 5, wherein the conductive adhesive body comprises thermosetting resin and conductive particles disposed in the thermosetting resin.

7. The bonding method of circuit board according to claim 5, wherein the insulating retaining walls comprises insulating resin.

8. The bonding method of circuit board according to claim 6, wherein the step s30 further comprises doping conductive particles with a predetermined proportion in liquid-state thermosetting resin in and adding a foaming agent into the liquid-state thermosetting resin and stirring the liquid-state thermosetting resin uniformly to form the conductive adhesive body solution and procure the conductive adhesive body solution to form the conductive adhesive bodies.

9. The bonding method of circuit board according to claim 8, wherein the thermosetting resin is at least one selected from a group consisting of modified phenolic resin, epoxy resin, and unsaturated polyester resin.

10. The bonding method of circuit board according to claim 5, wherein the step s50 further comprises adding a foaming agent into insulating resin solution and stirring the insulating resin solution uniformly to form an insulating retaining walls solution and dropping the insulating retaining walls solution between the adjacent conductive adhesive bodies to cure insulating retaining walls solution to form the insulating retaining walls.

11. The bonding method of circuit board according to claim 5, wherein the step s30, the step s40, and the step s50 are operated in a vacuum environment.

12. The bonding method of circuit board according to claim 5, wherein the substrate utilizes the first terminals to communicate with the circuit board.

13. A conductive adhesive, comprising a substrate, an insulating region formed on a surface of the substrate and a conductive region;
wherein the insulating region comprises a plurality of insulating retaining walls arranged along a same direction and in intervals; the conductive region comprises a plurality of conductive adhesive bodies; and the conductive adhesive bodies filled in gaps between the adjacent insulating retaining walls.

14. The conductive adhesive according to claim 13, wherein the conductive adhesive bodies comprise thermosetting resin and conductive particles disposed in the thermosetting resin.

15. The conductive adhesive according to claim 14, wherein the thermosetting resin is at least one selected from a group consisting of modified phenolic resin, epoxy resin, and unsaturated polyester resin.

16. The conductive adhesive according to claim 13, wherein the conductive particles are uniformly distributed in the thermosetting resin.
